(19) United States
(12) Patent Application Publication
(10) Pub. No.: US 2015/0263121 A1
(43) Pub. Date: Sep. 17, 2015

(54) SEMICONDUCTOR DEVICE AND METHOD OF MANUFACTURING THE SAME

(71) Applicant: KABUSHIKI KAISHA TOSHIBA, Minato-ku (JP)

(72) Inventors: Kana HIRAYAMA, Yokkaichi (JP); Ryuji Ohba, Yokkaichi (JP); Takeshi Kamigaichi, Yokkaichi (JP)

(73) Assignee: KABUSHIKI KAISHA TOSHIBA, Minato-ku (JP)

(21) Appl. No.: 14/483,601

(22) Filed: Sep. 11, 2014

Related U.S. Application Data
(60) Provisional application No. 61/952,322, filed on Mar. 13, 2014.

(51) Int. Cl. H01L 29/51; H01L 29/423; H01L 21/28; H01L 29/66; H01L 21/762; H01L 27/115; H01L 29/788; H01L 29/49

(52) U.S. Cl. CPC H01L 29/513; H01L 29/788; H01L 29/42364; H01L 29/4916; H01L 29/66825; H01L 21/76224; H01L 27/11521; H01L 27/11519; H01L 21/28008

(57) ABSTRACT

A semiconductor device including semiconductor substrate having an active region and an element isolation region, the active region isolated by the element isolation region, the element isolation region provided with an element isolation trench; a memory-cell transistor formed above the semiconductor substrate and having a gate electrode formed above the active region via a first insulating film, the gate electrode formed of a stack including a floating gate electrode, a first interelectrode insulating film, and a control gate electrode; an element isolation insulating film filled in the element isolation trench; and a second interelectrode insulating film disposed above the element isolation insulating film so as to form a stack of the second interelectrode insulating film and the control electrode above the element isolation insulating and a dielectric constant of the second interelectrode insulating film being higher than a dielectric constant of the first interelectrode insulating film.

### CROSS-REFERENCE TO RELATED APPLICATION(S)

This application is based upon and claims the benefit of priority from U.S. Provisional Patent Application No. 61/952,322, filed on, Mar. 13, 2014 the entire contents of which are incorporated herein by reference.

### FIELD

Semiconductor device and a method of manufacturing the same.

### BACKGROUND

Microfabrication of NAND flash memory devices is in progress to achieve larger storage capacity. As a result of microfabrication, a NAND flash memory device having a rocket-type cell structure is being manufactured in which the gate electrode of the memory-cell transistor is shaped like a rocket. In a device employing a rocket-type cell structure, processing of the features may become difficult as the aspect ratio increases or a gap fill error may occur during the formation of a control gate electrode. Development of flat-cell NAND flash memory device is expected to address such concerns.

In a flat-cell device, the use of a high-dielectric constant film is being proposed to serve as an interelectrode insulating film disposed between a floating gate electrode and a control gate electrode. In such structure, it is possible to reduce the programming voltage by increasing the capacitive coupling ratio of the floating gate electrode and the control gate electrode through increase in the dielectric constant of the interelectrode insulating film.

However, it is extremely difficult to form an insulating film possessing both high dielectric constant and high insulativity. Thus, increasing the dielectric constant of the interelectrode insulating film may degrade the insulativity of the interelectrode insulating film.

On the other hand, the attempt to maintain the high insulativity of the interelectrode insulating film may inhibit the reduction of the programming voltage due to failure in sufficiently increasing the dielectric constant.

### BRIEF DESCRIPTION OF THE DRAWINGS

FIG. 1 pertains to a first embodiment and is one example of an equivalent circuit diagram partially illustrating a memory cell array of a NAND flash memory device.

FIG. 2 is one schematic example of a plan view partially illustrating a layout pattern of a memory cell region.

FIG. 3 is one schematic example of a cross sectional view taken along line A-A of FIG. 2.

FIG. 4 is one schematic example of a cross sectional view taken along line B-B of FIG. 2.

FIG. 5 is one example of a cross sectional view taken along line A-A of FIG. 2 at one phase of a manufacturing process flow.

FIG. 6 is one example of a cross sectional view taken along line A-A of FIG. 2 at one phase of the manufacturing process flow.

FIG. 7 is one example of a cross sectional view taken along line A-A of FIG. 2 at one phase of the manufacturing process flow.

FIG. 8 is one example of a cross sectional view taken along line A-A of FIG. 2 at one phase of the manufacturing process flow.

FIG. 9 is one example of a cross sectional view taken along line A-A of FIG. 2 at one phase of the manufacturing process flow.

FIG. 10 is one example of a cross sectional view taken along line A-A of FIG. 2 at one phase of the manufacturing process flow.

FIG. 11 is one example of a cross sectional view taken along line A-A of FIG. 2 at one phase of the manufacturing process flow.

FIG. 12 pertains to a second embodiment and corresponds to FIG. 3.

FIG. 13 is one example of a cross sectional view taken along line A-A of FIG. 2 at one phase of the manufacturing process flow.

FIG. 14 is one example of a cross sectional view taken along line A-A of FIG. 2 at one phase of the manufacturing process flow.

### DETAILED DESCRIPTION

A semiconductor device including a semiconductor substrate having an active region and an element isolation region, the active region isolated by the element isolation region, the element isolation region provided with an element isolation trench; a memory-cell transistor formed above the semiconductor substrate and having a gate electrode formed above the active region via a first insulating film, the gate electrode formed of a stack including a floating gate electrode, a first interelectrode insulating film, and a control gate electrode; an element isolation insulating film filled in the element isolation trench; and a second interelectrode insulating film disposed above the element isolation insulating film so as to form a stack of the second interelectrode insulating film and the control electrode above the element isolation insulating film, and a dielectric constant of the second interelectrode insulating film being higher than a dielectric constant of the first interelectrode insulating film.

Embodiments are described hereinafter with reference to the drawings. In each of the embodiments, elements that are substantially identical are identified with identical reference symbols and are not re-described. However, the drawings are schematic and thus, do not reflect the actual measurements of the features such as the correlation of thickness to planar dimensions and the ratio of thicknesses of each of the layers.

### FIRST EMBODIMENT

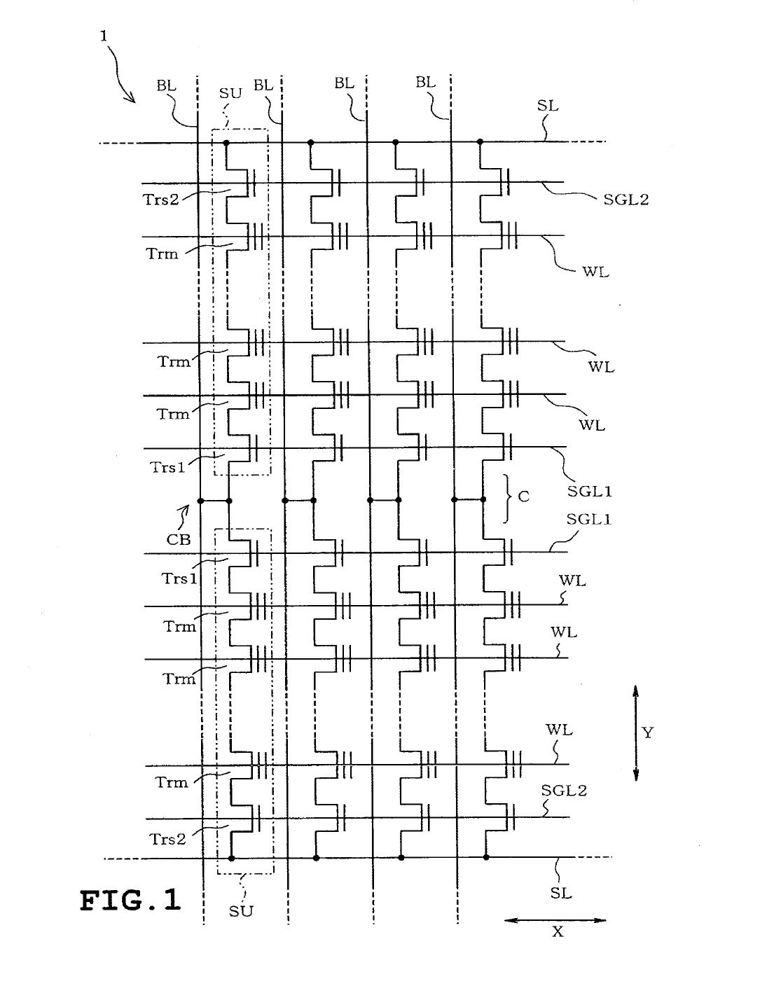

Referring first to FIG. 1, an equivalent circuit diagram is provided which partially illustrates a memory-cell array formed in a memory-cell region of a NAND flash memory device of a first embodiment. As illustrated in FIG. 1, the memory cell array of the NAND flash memory device is configured by NAND cell units SU arranged in rows and columns. NAND cell unit SU is configured by a couple of select-gate transistors Trs1 and Trs2 and series connected memory-cell transistors Trm (such as 32 in number) connected between the couple of select-gate transistors Trs1 and Trs2. The adjacent memory-cell transistors Trm within NAND cell unit SU share their source/drain regions.

Memory-cell transistors Trm aligned in the X direction (corresponding to word line direction, gate width direction) as viewed in FIG. 1 are interconnected by a common word line WL. Select-gate transistors Trs1 aligned in the X direction as viewed in FIG. 1 are interconnected by a common select-gate line SGL1 and select-gate transistors Trs2 are interconnected by a common select-gate line SGL2. The drain region of select-gate transistor Trs1 is connected to bit line contact CB. Bit line contact CB is connected to bit line BL extending in the Y direction (corresponding to gate length direction, bit line direction) orthogonal to the X direction as viewed in FIG. 1. Select-gate transistor Trs2 is connected to source line SL extending in the X-direction as viewed in FIG. 1 via a source region.

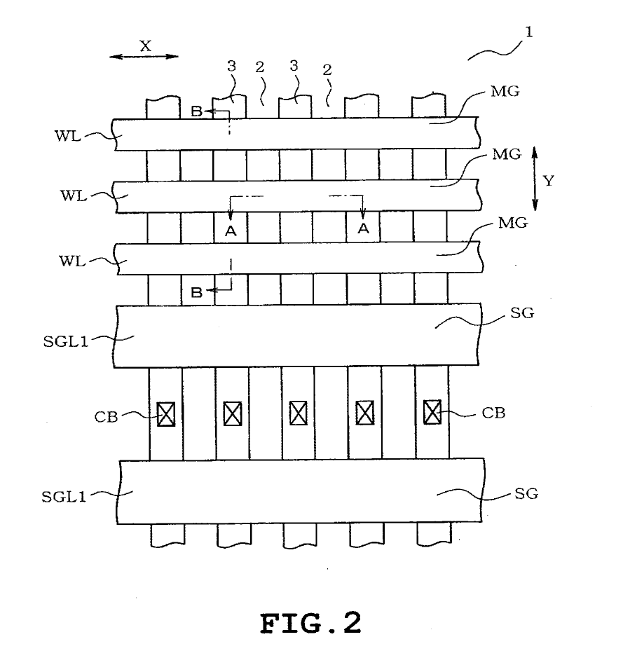

FIG. 2 is a plan view partially illustrating a layout pattern of the memory cell region. STIs 2 serving as element isolation regions extend along the Y direction as viewed FIG. 2 in silicon substrate 1 serving as a semiconductor substrate. STIs 2 are spaced from one another by a predetermined spacing in the X direction as viewed in FIG. 2. As a result, active regions 3, extending in the Y-direction as viewed in FIG. 2, are isolated in the X direction as viewed in FIG. 2. Word lines WL of memory-cell transistors Trm are formed so as to extend in the direction orthogonal to active regions 3 (the X direction as viewed in FIG. 2) and are spaced from one another in the Y direction as viewed in FIG. 2 by a predetermined spacing.

Further, pairs of select-gate lines SGL1 of the select-gate transistors are formed so as to extend along the X direction as viewed in FIG. 2. In each active region 3 located between the pairs of select-gate lines SGL1, bit line contact CB is formed. Above active region 3 intersecting with word line WL, gate electrode MG of the memory-cell transistor is formed. Above active region 3 intersecting with select-gate line SGL1, gate electrode SG of select-gate transistor is formed.

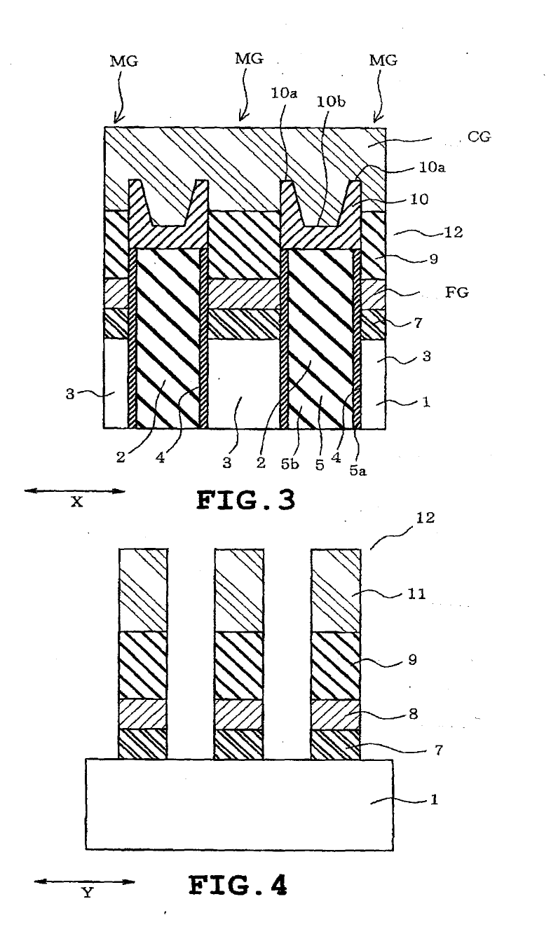

Referring to FIGS. 3 and 4, description will be given on flat-cell gate electrodes provided in the memory-cell region of the present embodiment. FIG. 3 is one example of a view schematically illustrating a cross section taken along line A-A (word line direction, X direction) of FIG. 2. FIG. 4 is one example of a view schematically illustrating a cross section taken along line B-B (bit line direction, Y direction) of FIG. 2.

Referring to FIGS. 3 and 4, element isolation trenches 4 are formed in an upper portion of silicon substrate 1 so as to be spaced from one another in the X direction. Element isolation trenches 4 isolate active region 3 in the X direction as viewed in FIG. 3. Element isolation insulating films 5 are formed in element. isolation trenches 4 to form element isolation regions (STI) 2. Element isolation insulating film 5 comes in the form of sidewall insulating film 5a and gap fill insulating film 5b. Sidewall insulating film 5a is formed of for example a silicon oxide or a silicon nitride. Gap fill insulating film 5b is formed of for example a silicon oxide.

Gate electrode MG of the memory-cell transistor is disposed above tunnel insulating film (first insulating film, gate insulating film) 7 formed above silicon substrate 1 (active region 3 of silicon substrate 1). Tunnel insulating film 7 is formed of for example a silicon oxide (SiO₂). Tunnel insulating film 7 is normally insulative, but allows flow of tunnel current when a voltage of a predetermined level within the drive voltage of the NAND flash memory device is applied. Source/drain region (not shown) is formed in the surface layer portion of silicon substrate 1 so as to be located in both sides of gate electrode MG.

Above tunnel insulating film 7, silicon film B is formed which is formed of a polycrystalline silicon. Silicon film 8 serves as floating gate electrode film FG which in turn serves as a charge storing laver. Above silicon film 8, first interelectrode insulating film (IPD film) 9 is formed for example which is formed of a silicate compound (that is, oxides of Hf (hafnium), Zr (zirconium), La ((lanthanum), and Al (aluminum)). The thickness of first interelectrode insulating film 9 is approximately 12 to 30 nm for example. The dielectric constant of first interelectrode insulating film 9 is approximately 6 to 25 for example when represented in relative dielectric constant and exhibits high insulativity. Appropriate compositional ratio is specified for the components of first interelectrode insulating film 9 in order to achieve the above described dielectric constant.

Further, the position of the upper surface of element isolation insulating film 5 in element isolation region 2 is configured to be located substantially in the middle of the thickness-wise direction of the first interelectrode insulating film. Above element isolation insulating film 5, second interelectrode insulating film (IPD film) 10 is formed which is formed of for example a silicate compound (that is, oxides of Hf (hafnium), Zr (zirconium), La (lanthanum), and Al (aluminum)). The dielectric constant of second interelectrode insulating film 10, which is approximately 10 to 30 for example when represented in relative dielectric constant, is higher than the dielectric constant film of first interelectrode insulating film 9 and possesses insulativity. Appropriate compositional ratio is specified for the components of second interelectrode insulating film 10. in order to achieve the above described dielectric constant. It is acceptable for the insulativity of the second interelectrode insulating film 10 to be less than the insulativity of the first interelectrode insulating film 9. In the present embodiment, the insulativity of the first interelectrode insulating film 9 is configured to be higher than the insulativity of second interelectrode insulating film 10.

At both X-direction ends of the upper surface of second interelectrode insulating film 10, projections 10a are formed. Further, the position of portion 10b located between projections 10a at the upper surface of second interelectrode insulating film 10 is formed so as to be lower than the position of the upper surface of the first interelectrode insulating film 9.

Floating gate electrode films FG are formed above silicon substrate 1 and are arranged in a matrix along the X direction and the Y direction. Between the stacks each formed of floating gate electrode film FG and first interelectrode insulating film 9. the upper portion of element isolation insulating film 5 and second interelectrode insulating film 10 are disposed.

Above first interelectrode insulating film 9 and second interelectrode insulating film 10, conductive film 11 formed of tungsten (W) for example is formed. Control gate electrode CG extending in the X direction is formed by conductive film 11.

In the above described structure, gate stack 12 extending in the X direction is formed by the upper portion of element isolation insulating film 5, tunnel insulating film 7, floating gate electrode FG, first interelectrode insulating film 9, and control gate electrode CG. More than one gate stack 12 is provided above silicon substrate 1. An interlayer insulating film (not shown) formed of a silicon oxide for example is formed between and above gate stacks 12. Above the interlayer insulating film, upper layer wirings (not shown) including bit lines are formed.

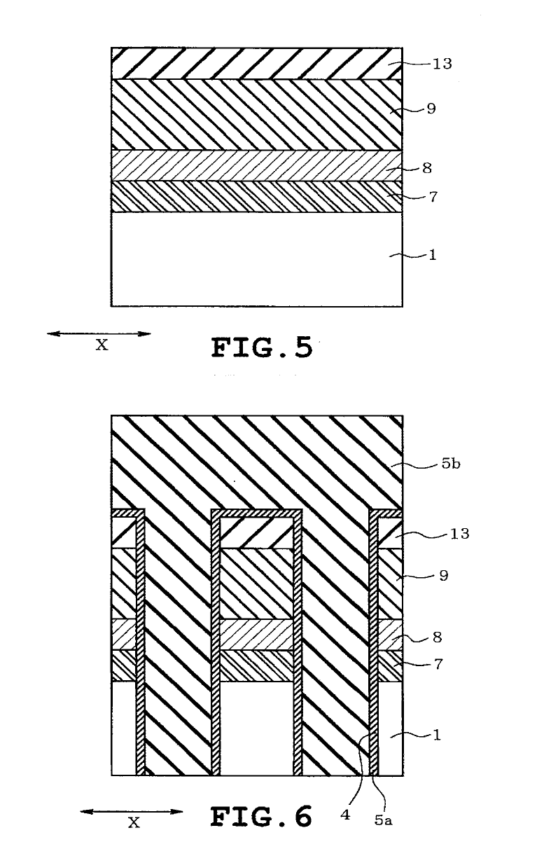

Next, a description is given on one example of a manufacturing method of the NAND flash memory device of the present embodiment with reference to FIGS. 5 to 11. FIGS. 5 to 11 schematically illustrate one phase of the manufacturing process flow of the cross sectional structure corresponding to FIG. 3.

First, as shown in FIG. 5, tunnel insulating film 7 formed of a silicon oxide for example is formed above silicon substrate 1. Then, silicon film 8 formed of a polycrystalline silicon is formed above tunnel insulating film 7. The materials used are not limited in particular. Next, first interelectrode insulating film 9 formed of for example a silicate compound (that is, oxides of Hf, Zr, La, and Al) are formed above silicon film 8. First interelectrode insulating film 9 has a relative dielectric constant of approximately 6 to 25 for example. Further, above first interelectrode insulating film 9, CMP (chemical mechanical polishing) stopper film 13 is formed which is formed of a silicon nitride film for example.

Then, a photoresist (not shown) is coated above CMP stopper film 13 and the resist is patterned by exposure and development. Next, using the patterned resist as a mask, element isolation trenches 4 (refer to FIG. 6) are formed by etching CMP stopper film 13, first interelectrode insulating film 9, silicon film 8, tunnel insulating film 7, and silicon substrate 1 by RIE (reactive ion etching) for example.

Next, sidewall insulating film 5a (refer to FIG. 6) formed of a silicon oxide or a silicon nitride for example is formed across the entire surface. Subsequently, silicon oxide film (gap fill insulating film) 5b formed of a polysilazane (PSI) for example is formed along sidewall insulating film 5a using a coating technique for example as illustrated in FIG. 6. As a result, the structure illustrated in FIG. 6 is obtained.

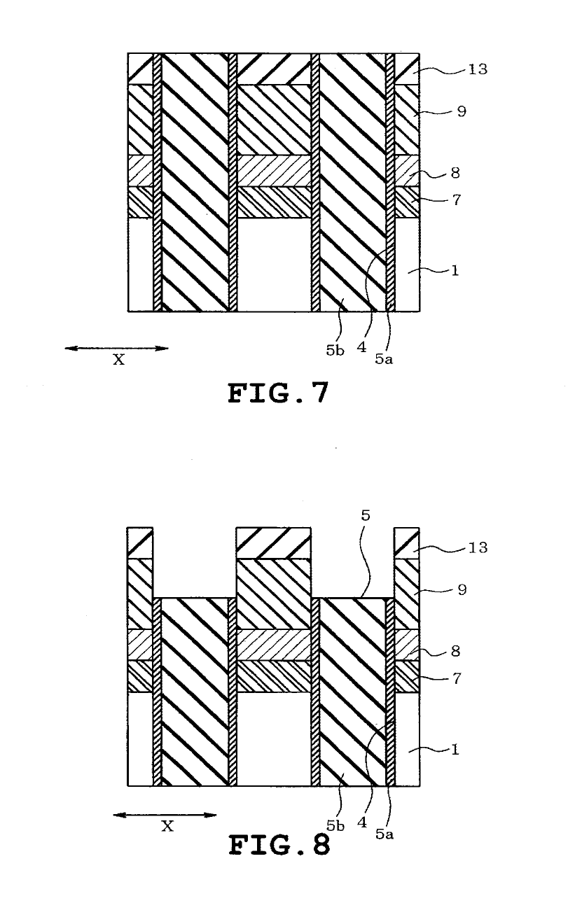

Then, as illustrated in FIG. 7, planarization is carried out using CMP (chemical mechanical polishing) for example until the upper surface of CMP stopper film 13 is exposed. Subsequently, gap fill insulating film 5b and sidewall insulating film 5a, in other words, element isolation insulating film 5 is etched back by wet etching for example as illustrated in FIG. 8. As a result, element isolation insulating film 5 is formed in which the position of the upper surface of element isolation insulating film 5 is lower than the position of the upper surface of the first interelectrode insulating film 9 and higher than the position of the under surface of first interelectrode insulating film 9.

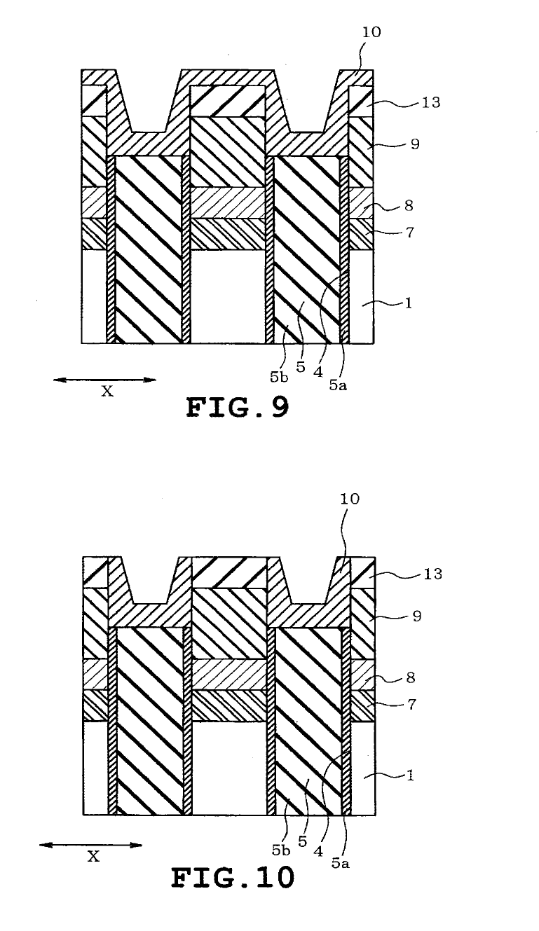

Then, as illustrated in FIG. 9, second interelectrode insulating film 10 is formed above the entire surface (the upper surface of CMP stopper film 13, the side surface of CMP stopper film 13, the side surface of first interelectrode insulating film 9, and the upper surface of element isolation insulating film 5). Second interelectrode insulating film 10 is formed of for example a silicate compound (that is, oxides of Hf, Zr, La, and Al). The dielectric constant of second interelectrode insulating film 10, which is approximately 10 to 30 for example when represented in relative dielectric constant, is higher than the dielectric constant film of first interelectrode insulating film 9.

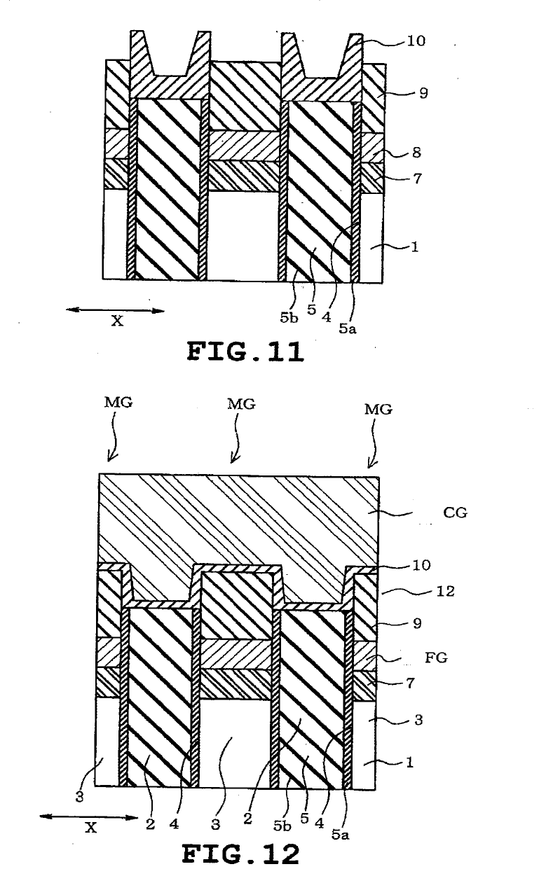

Then, as illustrated in PIG. 10, planarization is carried out using CMP for example until, the upper surface of CMP stopper film 10 is exposed. Thereafter, CMP stopper film 13 is removed by wet etching for example as illustrated in FIG. 11. Subsequently, above first interelectrode insulating film 9 and second interelectrode insulating film 10, conductive film 11 formed of tungsten (W) for example is formed by sputtering for example as illustrated in FIG. 3.

Thereafter, a line-and-space patterned hard mask (not shown) is formed so as to extend in the X direction. Then, anisotropic etching is performed using the hard mask as a mask to selectively remove conductive film 11, first interelectrode insulating film 9, second interelectrode insulating film 10, silicon film 8, tunnel insulating film 7, and the upper portion of element isolation insulating film 5 (refer to FIG. 4). As a result, gate stacks 12 extending in the X direction are formed.

In the above described structure, silicon film 8 is isolated along the X direction and the Y direction and serve as floating gate electrodes FG aligned in a matrix. Further, first interelectrode insulating film 9 and second interelectrode insulating film 10 serve as the IPD film. Still further, conductive film 11 is shaped into stripes extending in the X direction and serve as control gate electrodes CG.

Next, a silicon oxide film for example is deposited across the entire surface and thereafter planarized to form an interlayer insulating film (not shown) between and above gate stacks 12. Then, upper-laver wirings (riot shown) including hit lines are formed above the interlayer insulating film.

In the present embodiment structured as described above, the dielectric constant of second interelectrode insulating film 10 above STI 2 is configured to be greater than the dielectric constant of first interelectrode insulating film 9 above active region 3 as illustrated in FIG. 3. In other words, first interelectrode insulating film 9 above active region 3 is configured as a film having high resistivity and second interelectrode insulating film 10 above STI 2 is configured as a film having high dielectric constant. As result, it is possible to reduce the programming voltage of the memory-cell transistor while maintaining the high resistivity of the interelectrode insulating film (IPD). Further, reduction in the programming voltage of the memory-cell transistor reduces the level of voltage applied between control gate electrodes CG which enables downsizing of the memory-cell itself. Further, reduction in the programming voltage also leads to reduction of the level of voltage applied by the peripheral circuit, which enables the downsizing of the peripheral circuit as well.

Further, in the above described embodiment, projections 10a are formed at both X-direction ends of the upper surface of second interelectrode insulating film 10. As a result, it is possible to reduce the programming voltage even more effectively.

### SECOND EMBODIMENT

FIGS. 12 and 14 illustrate a second embodiment. Structures identical to the first embodiment are identified with identical reference symbols. In the second embodiment, second interelectrode insulating film 10 is formed above first interelectrode insulating film 9 and second interelectrode insulating film 10 is configured to remain above first interelectrode insulating film 9 as illustrated in FIG. 12.

More specifically, second interelectrode insulating film 10 is formed above the upper surface of first interelectrode insulating film 9, the side surface of first interelectrode insulating film 9, and the upper surface of element isolation insulating film 5 as illustrated in FIG. 12. Above second interelectrode insulating film 10, conductive film 11 is formed which is formed of tungsten for example.

In the above described structure, gate stack 12 extending in the X direction is formed by the upper portion of element isolation insulating film 5, tunnel insulating film 7, floating gate electrode FG, first interelectrode insulating film 9, second interelectrode insulating film 10, and control gate electrode CG. More than one gate stack 12 is provided above silicon substrate 1. Between and above gate stacks 12, interlayer insulating film (not shown) is provided which is formed of a silicon oxide for example. Above the interlayer insulating film, upper layer wirings (not shown) including bit lines are formed.

Next, a description will be given one example of a second embodiment of the NAND flash memory device with reference to FIGS. 12, 13, and 14. FIGS. 12, 13, and 14 schematically illustrate one phase of the manufacturing process flow of the cross-sectional structure illustrated in FIG. 3.

The manufacturing process flow up to FIGS. 5 to 8 (the step of etching back element isolation insulating film 5) of the first embodiment remain the same in the manufacturing process flow of the second embodiment.

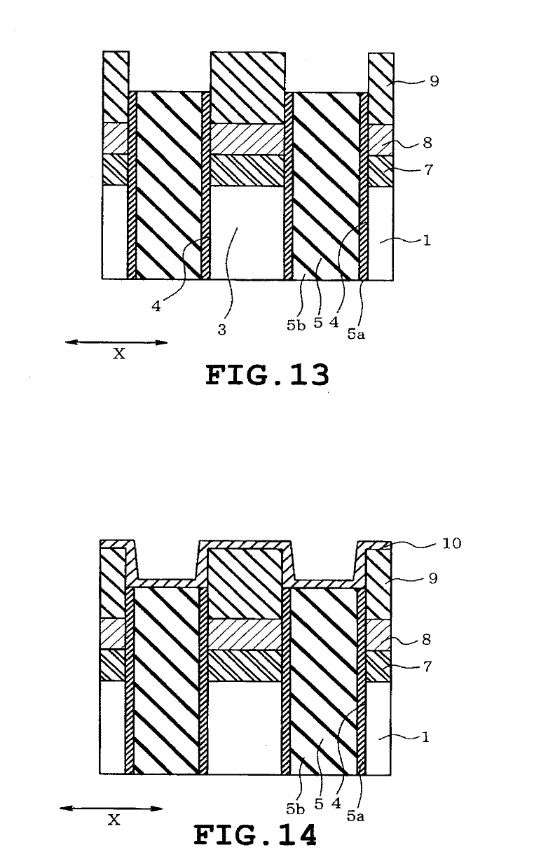

Next, CMP stopper film 13 is removed as illustrated in FIG. 13.

Then, second interelectrode insulating film 10 is formed above the entire surface (the upper surface of first interelectrode insulating film 9, the side surface of first interelectrode insulating film 9, and the upper surface of element isolation insulating film 5) as illustrated in FIG. 14. Second interelectrode insulating film 10 is formed of a silicate compound (that is, oxides of, Hf, Zr, La, and Al) for example. Second interelectrode insulating film 10 has a dielectric constant, approximately 10 to 30 in relative dielectric constant, which is higher than the dielectric constant of first interelectrode insulating film 9.

Then, conductive film 11 formed of tungsten (b) for example, is formed above second interelectrode insulating film 10 by sputtering for example as illustrated in FIG. 12. The rest of the process steps remain the same from those of the first embodiment.

Other than those described above, the structures of the second embodiment are the same as the structures of the first embodiment. Thus, it is possible to obtain the operation and effect substantially the same as those of the first embodiment in the second embodiment as well. Especially in the second embodiment, second interelectrode insulating film 10 is configured to remain above the first interelectrode insulating film 9 disposed above active region 3. Thus, it is possible to reduce the number of process steps as compared to the first embodiment.

### OTHER EMBODIMENTS

The following structure maybe employed in addition to the embodiments described above. In each of the above described embodiments, first interelectrode insulating film 9 and second interelectrode insulating film 10 were formed of oxides of Hf, Zr, La, and Al. Apart from such materials, an insulating film may be formed by combining compounds having dielectric constants higher than a silicon oxide to obtain the desired dielectric constant.

For example, an insulating film may be formed by combining one or more of hafnia, hafnium silicate, alumina, hafnium aluminate, lanthanum oxide, lanthanum aluminate, yttrium oxide, yttrium aluminate, titanium oxide, tantalum oxide, silicon nitride, silicon nitride containing oxygen, and the like to obtain the desired dielectric constant.

Further, each of the above described embodiments were described through a NAND flash memory device application, however, other semiconductor devices provided with a flat-cell structure are also applicable.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semi conductor device comprising:
a semiconductor substrate having an active region and an element isolation region, the active region being isolated by the element isolation region, the element isolation region being provided with an element isolation trench;
a memory-cell transistor being formed above semiconductor substrate and having a gate electrode formed above the active region via a first insulating film, the gate electrode being formed of a stack including a. floating gate electrode, a first interelectrode insulating film, and a control gate electrode;
an element isolation insulating film filled in the element isolation trench; and
a second interelectrode insulating film being disposed above the element isolation insulating film so as to form a stack of the second interelectrode insulating film and the control electrode above the element isolation insulating film, and
a dielectric constant of the second interelectrode insulating film being higher than a dielectric constant of the first interelectrode insulating film.

2. The semiconductor device according to claim 1, wherein an insulativity of the first interelectrode insulating film is higher than an insulativity of the second interelectrode insulating film.

3. The semiconductor device according to claim 1, wherein the first interelectrode insulating film and the second interelectrode insulating film are formed of a silicate compound.

4. The semiconductor device according to claim 1, wherein a position of an upper surface of the element isolation insulating film is lower than a position of an upper surface of the first interelectrode insulating film and higher than an under surface of the first interelectrode insulating film.

5. The semiconductor device according to claim 1, wherein the element isolation region extends in a first direction and a projection is formed at both ends of an upper surface of the second interelectrode insulating film, the both ends located along a direction orthogonal to the first direction.

6. The semiconductor device according to claim 5, wherein a position of a portion between the projections at the upper surface of the second interelectrode insulating film is lower than a position of an upper surface of the first interelectrode insulating film.

7. The semiconductor device according to claim 1, wherein the element isolation region extends in a first direction, and the control gate electrode extends in a second direction crossing the first direction, the first insulating film, the floating gate electrode, and the first interelectrode insulating film being disposed above the active region and being isolated in the first direction and the second direction.

8. The semiconductor device according to claim 7, wherein the second interelectrode insulating film is disposed above the element isolation insulating film and is isolated in the first direction and the second direction.

9. The semiconductor device according to claim 1, wherein the floating gate electrode is formed of a polycrystalline silicon.

10. A semiconductor device comprising:
a semiconductor substrate having an active region and an
element isolation region, the active region being isolated by the element isolation region, the element isolation region being provided with an element isolation trench;
memory-cell transistor being formed above the semiconductor substrate and having a gate electrode formed above the active region via a first insulating film, the gate electrode being formed of a stack including a floating gate electrode, a first interelectrode insulating film, a second interelectrode insulating film, and a control gate electrode; and
an element isolation insulating film filled in the element isolation trench;
the second interelectrode insulating film being disposed above the element isolation insulating film so as to form a stack of the second interelectrode insulating film and the control electrode above the element isolation insulating film, and
a dielectric constant of the second interelectrode insulating film being higher than a dielectric constant of the first interelectrode insulating film.

11. The semiconductor (device according to claim 10, wherein the first interelectrode insulating film is formed of a silicate compound.

12. The semiconductor device according to claim 10, wherein the second interelectrode insulating film is formed of a silicate compound.

13. The semiconductor device according to claim 10, wherein a position of an upper surface of the element isolation insulating film is lower than a position of an upper surface of the first, interelectrode insulating film and higher than an under surface of the first interelectrode insulating film.

14. The semiconductor device according to claim 10, wherein a position of an upper surface of a portion of the second interelectrode insulating film formed above the element isolation insulating film is lower than a position of an upper surface of the first interelectrode insulating film.

15. The semiconductor device according to claim 10, wherein the element isolation region extends in a first direction and the control gate electrode and the second interelectrode insulating film extend in a second direction crossing the first direction, the first insulating film, the floating gate electrode, and the first interelectrode insulating film being disposed above the active region and being isolated in the first direction and the second direction.

16. The semiconductor device according to claim 10, wherein the floating gate electrode is formed of a polycrystalline silicon.

17. A method of manufacturing a semiconductor device comprising:
forming a first insulating film above a semiconductor substrate;
forming a floating gate electrode above the first insulating film;
forming a first, interelectrode insulating film above the floating gate electrode;
forming an element isolation trench into the first interelectrode insulating film, the floating gate electrode, the first insulating film, and the silicon substrate;
filling an insulating film into the element isolation trench;
lowering a position of an upper surface of the element isolation insulating film;
forming a second interelectrode insulating film having a dielectric constant higher than a dielectric constant of the first interelectrode insulating film above the first interelectrode insulating film and the element isolation insulating film; and
forming a control gate electrode above the second interelectrode insulating film.

18. The method of manufacturing a semiconductor device according to claim 17, wherein lowering the position of the upper surface of the element isolation insulating film lowers the position of the upper surface of the element isolation insulating film so as to be lower than a position of an upper surface of the first interelectrode insulating film and higher than an under surface of the first interelectrode insulating film.

19. The method of manufacturing a semiconductor device according to claim 17, further comprising removing a portion of the second interelectrode insulating film formed above the first interelectrode insulating film after forming the second interelectrode insulating film and before forming the control electrode.

20. The method of manufacturing a semiconductor device according to claim 19, wherein the element isolation region extends in a first direction and a projection is formed at both ends of an upper surface of the second interelectrode insulating film, the both ends located along a direction orthogonal to the first direction.
